(19) United States
(12) Patent Application Publication
(10) Pub. No.: US 2026/0128476 A1
(43) Pub. Date: May 7, 2026

(54) PRINTED CIRCUIT BOARD AND BATTERY MODULE INCLUDING SAME

(71) Applicant: Samsung SDI Co., Ltd., Yongin-si (KR)

(72) Inventor: Min-Jin Kim, Yongin-si (KR)

(73) Assignee: Samsung SDI Co., Ltd., Yongin-si (KR)

(21) Appl. No.: 19/273,677

(22) Filed: Jul. 18, 2025

(30) Foreign Application Priority Data
Nov. 7, 2024 (KR) 10-2024-0156959

(51) Int. Cl. H01M 50/519; H01M 50/209; H01M 50/507; H01R 12/53; H05K 1/02

(52) U.S. Cl. CPC H01M 50/519; H01M 50/209; H01M 50/507; H01R 12/53; H05K 1/0298; H05K 2201/09036

(57) ABSTRACT

The present disclosure provides a printed circuit board and a battery module including the same. A printed circuit board may include a first signal wiring layer, a second signal wiring layer disposed spaced apart from the first signal wiring layer along a first direction, a first insulating layer disposed between the first signal wiring layer and the second signal wiring layer; and a first insertion groove which is formed on a first side surface of the first insulating layer and into which a terminal of a first cable can be inserted, wherein at least one of the first signal wiring layer or the second signal wiring layer includes a connection pattern disposed on one side thereof in contact with the first insertion groove and configured to be electrically connectable to the terminal of the first cable.

### CROSS-REFERENCE TO RELATED APPLICATIONS

This present application claims priority to and the benefit under 35 U.S.C. §119(a)-(d) of Korean Patent Application No. 10-2024-0156959, filed on Nov. 7, 2024, in the Korean Intellectual Property Office, the entire disclosure of which is incorporated herein by reference.

### FIELD

The present disclosure relates to a printed circuit board and a battery module including the same.

### BACKGROUND

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

A battery module including a plurality of battery cells may include a printed circuit board.

A printed circuit board may electrically connect a plurality of electronic circuit components. The printed circuit board may include a plurality of layers. At least one of the plurality of layers may include a pattern formed of a conductive metal, such as copper. An insulating layer may be placed between the layers having a metal pattern formed therein, and the layers having a pattern formed therein may be connected through vias. For example, the via may include a through hole, a blind via, and/or a buried via.

The printed circuit board may be connected to battery cells, etc., and may be used for a protection circuit module (PCM) and a battery management system (BMS) to prevent accidents caused by batteries, etc.

The above information disclosed in this Background section is for enhancement of understanding of the background of the present disclosure, and therefore, it may contain information that does not constitute related (or prior) art.

### SUMMARY

The present disclosure provides a printed circuit board and a battery module including the same for solving one or more problems described herein.

These and other aspects and features of the present disclosure will be described in or will be apparent from the following description of embodiments of the present disclosure.

To solve the one or more technical problems described herein, a printed circuit board may include a first signal wiring layer, a second signal wiring layer disposed spaced apart from the first signal wiring layer along a first direction, a first insulating layer disposed between the first signal wiring layer and the second signal wiring layer and a first insertion groove that is formed on a first side surface of the first insulating layer and configured such that a terminal of a first cable can be inserted therein, wherein at least one of the first signal wiring layer or the second signal wiring layer includes a connection pattern which is disposed on one side thereof in contact with the first insertion groove and configured to be electrically connected to the terminal of the first cable.

According to one or more embodiments, the first signal wiring layer may include a first connection pattern disposed on the one side thereof in contact with the first insertion groove, the second signal wiring layer may include a second connection pattern disposed on the one side thereof in contact with the first insertion groove, and the first connection pattern and the second connection pattern may be configured to be electrically connected to the terminal of the first cable, respectively.

According to one or more embodiments, the first insulating layer may include a core layer or a prepreg layer.

According to one or more embodiments, the printed circuit board may further include a third signal wiring layer disposed on the second signal wiring layer; and a second insulating layer disposed between the second signal wiring layer and the third signal wiring layer, wherein at least a portion of the first insertion groove may be formed on one side surface of the second insulating layer.

According to one or more embodiments, a length of the second signal wiring layer in a second direction intersecting the first direction may be shorter than a length of the first signal wiring layer or the third signal wiring layer in the second direction.

According to one or more embodiments, the first insulating layer may include one of a core layer and a prepreg layer, and the second insulating layer may include the other of the core layer or the prepreg layer.

According to one or more embodiments, the printed circuit board may further include a fourth signal wiring layer disposed on the third signal wiring layer and a third insulating layer disposed between the third signal wiring layer and the fourth signal wiring layer, wherein at least a portion of the first insertion groove may be formed on one side surface of the third insulating layer.

According to one or more embodiments, the printed circuit board may further include a third signal wiring layer disposed on the second signal wiring layer, a second insulating layer disposed between the second signal wiring layer and the third signal wiring layer, a fourth signal wiring layer disposed on the third signal wiring layer, a third insulating layer disposed between the third signal wiring layer and the fourth signal wiring layer and a second insertion groove which is formed on a second side surface of at least one of the first to third insulating layers and configured such that a terminal of a second cable can be inserted therein, wherein at least one of two signal wiring layers respectively contacting both sides of the second insertion groove located opposite to one another in the first direction may include a connection pattern that is disposed on one side thereof in contact with the second insertion groove and configured to be electrically connected to a terminal of the second cable.

According to one or more embodiments, one of the two signal wiring layers may include a third connection pattern disposed on one side thereof in contact with the second insertion groove, the other of the two signal wiring layers may include a fourth connection pattern disposed on one side thereof in contact with the second insertion groove, and the third connection pattern and the fourth connection pattern may be configured to be electrically connected to the terminal of the second cable, respectively.

According to one or more embodiments, at least one of the two signal wiring layers may be different from at least one of the two signal wiring layers that are in contact with opposite sides along the first direction of the first insertion groove.

According to one or more embodiments, the second side surface may be a surface parallel to the first side surface.

According to one or more embodiments, a plane including the second side surface may intersect a plane including the first side surface.

According to one or more embodiments, a thickness of the first insertion groove in the first direction may be smaller than a thickness of the terminal of the first cable in the first direction.

According to one or more embodiments, the printed circuit board may further include a cable holder that is disposed on at least one of the first signal wiring layer or the second signal wiring layer and configured to engage with the terminal of the first cable.

According to one or more embodiments, a planar shape of an opening of the insertion groove may be rectangular.

To solve the one or more technical problems described herein, a battery module may include a plurality of battery cells, a printed circuit board including a first insulating layer, and a first signal wiring layer and a second signal wiring layer spaced apart from one another in a first direction with the first insulating layer interposed therebetween, and a bus bar that electrically connects the plurality of battery cells and the printed circuit board, wherein the printed circuit board further includes a first insertion groove that is formed on a first side surface of the first insulating layer and into which a terminal of a first cable can be inserted, and at least one of the first signal wiring layer or the second signal wiring layer includes a connection pattern which is disposed on one side thereof in contact with the first insertion groove and configured to be electrically connected to the terminal of the first cable.

According to one or more embodiments, the first signal wiring layer may include a first connection pattern on the one side in contact with the first insertion groove, the second signal wiring layer may include a second connection pattern on the one side in contact with the first insertion groove, the first connection pattern and the second connection pattern may be configured to be electrically connectable to the terminal of the first cable, respectively.

According to one or more embodiments, the battery module may further include a third signal wiring layer disposed on the second signal wiring layer, a second insulating layer disposed between the second signal wiring layer and the third signal wiring layer, a fourth signal wiring layer disposed on the third signal wiring layer and a third insulating layer disposed between the third signal wiring layer and the fourth signal wiring layer, wherein at least a portion of the first insertion groove may be formed on one side of at least one of the second insulating layer or the third insulating layer.

According to one or more embodiments, the battery module may further include a third signal wiring layer disposed on the second signal wiring layer, a second insulating layer disposed between the second signal wiring layer and the third signal wiring layer, a fourth signal wiring layer disposed on the third signal wiring layer, a third insulating layer disposed between the third signal wiring layer and the fourth signal wiring layer and a second insertion groove which is formed on a second side surface of at least one of the first to third insulating layers and into which a terminal of a second cable can be inserted, wherein at least one of two signal wiring layers respectively contacting both sides of the second insertion groove located opposite to one another in the first direction may include a connection pattern disposed on one side thereof in contact with the second insertion groove and configured to be electrically connected to a terminal of the second cable.

According to one or more embodiments, one of the two signal wiring layers may include a third connection pattern on one side in contact with the second insertion groove, the other of the two signal wiring layers may include a fourth connection pattern on one side thereof in contact with the second insertion groove, the third connection pattern and the fourth connection pattern may be configured to be electrically connected to the terminal of the second cable, respectively, and at least one of the two signal wiring layers may be different from at least one of the two signal wiring layers that are in contact with opposite sides along the first direction of the first insertion groove.

According to some embodiments of the present disclosure, a printed circuit board may include an insertion groove on a side surface thereof into which a terminal of a cable may be inserted and connected without a connector, so that a separate additional process, such as soldering, required when mounting a connector on a printed circuit board may be omitted, and problems such as defects and corrosion of the connector caused by such a process may be eliminated.

According to some embodiments of the present disclosure, a printed circuit board may be connected to an externally located element/equipment/device without a separate connector, and two layers spaced apart inside the printed circuit board can be electrically connected through a terminal of a cable connected to an insertion groove formed on a side surface of the printed circuit board, thereby securing freedom in pattern design.

According to some embodiments of the present disclosure, the printed circuit board of the battery module includes an insertion groove on the side surface into which a terminal of a cable may be inserted and connected without a connector, thereby reducing a failure of the battery module caused by a structural abnormality or poor connection of the connector.

However, aspects and features of the present disclosure are not limited to those described above, and other aspects and features not mentioned will be clearly understood by a person skilled in the art from the detailed description, described below.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1A illustrates a cross-sectional view of a printed circuit board according to exemplary embodiments;

FIG. 1B illustrates a cross-sectional view of the printed circuit board according to exemplary embodiments, viewed from a different direction than FIG. 1A;

FIG. 1C illustrates a cross-sectional view of the printed circuit board according to exemplary embodiments of FIG. 1A into which a terminal of a cable is inserted;

FIG. 1D illustrates a perspective view of a printed circuit board and a cable that may be inserted into the printed circuit board according to exemplary embodiments;

FIG. 2 illustrates a cross-sectional view of the printed circuit board according to exemplary embodiments;

FIG. 3 illustrates a cross-sectional view of a printed circuit board according to exemplary embodiments;

FIG. 4 illustrates a cross-sectional view of a printed circuit board according to exemplary embodiments;

FIG. 5 illustrates a cross-sectional view of a printed circuit board according to exemplary embodiments;

FIG. 6 illustrates a cross-sectional view of a printed circuit board according to exemplary embodiments; and

FIG. 7 illustrates a perspective view of a battery module according to exemplary embodiments.

### DETAILED DESCRIPTION

Hereinafter, embodiments of the present disclosure will be described, in detail, with reference to the accompanying drawings. The terms or words used in the present specification and claims are not to be limitedly interpreted as general or dictionary meanings and should be interpreted as meanings and concepts that are consistent with the technical idea of the present disclosure on the basis of the principle that an inventor can be his/her own lexicographer to appropriately define concepts of terms to describe his/her invention in the best way.

The embodiments described in this specification and the configurations shown in the drawings are only some of the embodiments of the present disclosure and do not represent all of the technical spirit, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As

used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element. In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

As described herein, a printed circuit board may include a plurality of layers. Layers having a pattern formed therein may be connected through vias. In this circumstance, it may be most economical to form through-holes for electrical connections between layers having metal patterns formed therein, but because the through-holes penetrate all layers, the patterns of inner layers need to be designed to avoid the through-holes, which reduces the degree of freedom in pattern design.

According to some embodiments of the present disclosure, a printed circuit board may be connected to an externally located element without a separate connector, and layers spaced apart inside the printed circuit board can be electrically connected through a terminal of a cable connected to an insertion groove formed on a side surface of the printed circuit board, thereby securing freedom in pattern design.

Further, according to some embodiments of the present disclosure, a printed circuit board may include an insertion groove on a side surface thereof into which a terminal of a cable may be inserted and connected without a connector, so that a separate additional process, such as soldering, required when mounting a connector on a printed circuit board may be omitted, and problems such as defects and corrosion of the connector caused by such a process may be eliminated. Failure of the battery module caused by a structural abnormality or poor connection of the connector can also be reduced.

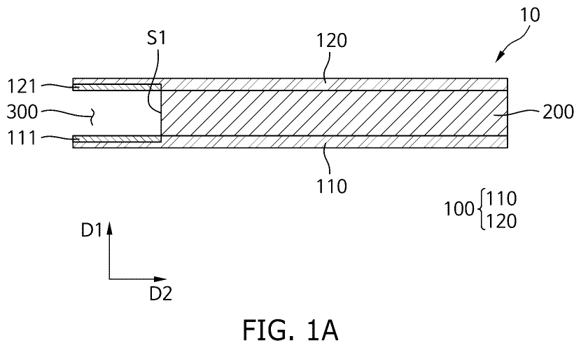

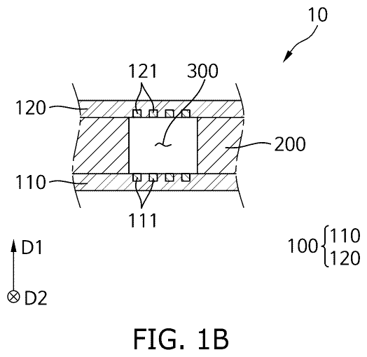

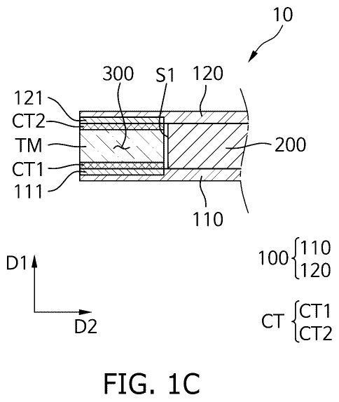

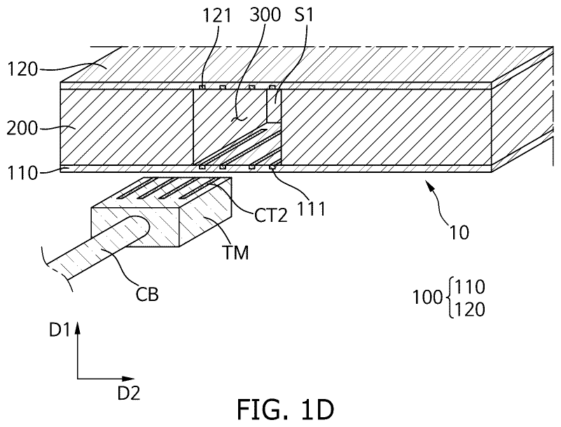

FIG. 1A is a cross-sectional view of a printed circuit board according to exemplary embodiments. FIG. 1B is a cross-sectional view of the printed circuit board of FIG. 1A, viewed from a different direction than FIG. 1A. FIG. 1C is a cross-sectional view of the printed circuit board of FIG. 1A into which a terminal of a cable is inserted. FIG. 1D is a perspective view illustrating a printed circuit board and a cable that may be inserted into the printed circuit board according to exemplary embodiments.

Referring to FIGS. 1A to 1D, a printed circuit board 10 according to exemplary embodiments may include a first signal wiring layer 110, a second signal wiring layer 120 disposed spaced apart from the first signal wiring layer 110 along a first direction D1, an insulating layer 200 disposed between the first signal wiring layer 110 and the second signal wiring layer 120, and an insertion groove 300 which is formed on a first side surface S1 of the insulating layer 200 and into which a cable CB may be inserted.

At least one of the first signal wiring layer 110 or the second signal wiring layer 120 may include a connection pattern that is disposed on one side thereof in contact with the insertion groove 300 and is configured to be electrically connected to a terminal TM of the cable CB. For example, the first signal wiring layer 110 may include a first connection pattern 111 disposed on one side in contact with the insertion groove 300, and the second signal wiring layer 120 may include a second connection pattern 121 disposed on one side in contact with the insertion groove 300. In this circumstance, the first connection pattern 111 and the second connection pattern 121 may be electrically connected to the terminal TM of the cable(s) CB, respectively. The terminal TM may include contacts CT1, CT2 on its upper and lower surfaces, respectively. For example, the first contact CT1 may be electrically connectable by coming into contact with the first connection pattern 111, and the second contact CT2 may be electrically connectable by coming into contact with the second connection pattern 121.

The printed circuit board 10 according to exemplary embodiments may be connected to the terminal TM of the cable CB through the insertion groove 300. Through this, the printed circuit board 10 may be electrically connected to another printed circuit board or an external device/system to receive a signal therefrom, and the received signal may be transmitted to the first signal wiring layer 110 and the second signal wiring layer 120 electrically connected to the cable CB.

The printed circuit board 10 according to exemplary embodiments may have a structure to include at least two signal wiring layers 100, in which the at least two signal wiring layers 100 are stacked along one direction. For example, the signal wiring layers 100 may include a first signal wiring layer 110 and a second signal wiring layer 120. One or more electronic components may be mounted on at least one of the signal wiring layers disposed on both outer surfaces along the first direction D1 of the printed circuit board 10, and the signal wiring layer 100 disposed on the surface and the electronic components may be electrically connected.

For example, referring to FIG. 1A, a first signal wiring layer 110 and a second signal wiring layer 120 may be disposed on both outer surfaces along the first direction D1 of the printed circuit board 10. Here, one or more electronic components may be mounted on the first signal wiring layer 110 and/or the second signal wiring layer 120.

The length of the first signal wiring layer 110 along a second direction D2 intersecting or perpendicular to the first direction D1 may be substantially equal to the length of the second signal wiring layer 120 along the second direction D2. That is, the first signal wiring layer 110 and the second signal wiring layer 120 located on both outer surfaces along the first direction D1 of the printed circuit board 10 may have the same length. However, without being limited thereto, the length of the first signal wiring layer 110 along the second direction D2 may be different from the length of the second signal wiring layer 120 along the second direction D2.

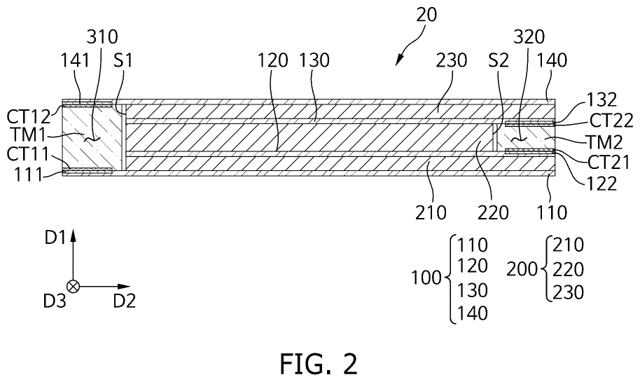

The printed circuit board 10 may include an even number (two or more) of signal wiring layers 100. According to some embodiments, the printed circuit board 10 may include four signal wiring layers 100 (see e.g., FIG. 2). In this circumstance, the first to fourth signal wiring layers 100 may be sequentially stacked along one direction, and an insulating layer 200 may be placed between signal wiring layers 100. According to some embodiments, the printed circuit board 10 may include six, eight, or ten signal wiring layers 100. However, without being limited thereto, the printed circuit board 10 may include an odd number of signal wiring layers 100.

According to some embodiments, a hole or via that electrically connects two or more signal wiring layers 100 may be provided between the signal wiring layers 100. The hole or via may be provided through the insulating layer 200. The hole may electrically connect the signal wiring layers 100 disposed on both outer surfaces to each other (or one another). The via may electrically connect at least one of the signal wiring layers 100 disposed on both outer surfaces to a signal wiring layer 100 located inside the printed circuit board 10, or may electrically connect two signal wiring layers 100 located inside to each other.

The signal wiring layer 100 may include a pattern (for example, a conductive pattern or a metal pattern). For example, the pattern may be a copper pattern. The pattern may configure a circuit that electrically connects one or more electrical elements disposed on the signal wiring layer 100. The pattern may include a connection pattern, and the connection pattern may be a portion of a pattern that connects a signal wiring layer 100 including the pattern to another signal wiring layer 100 or to another printed circuit board. The connection pattern may be electrically connected to the terminal TM by contacting a contact CT of the terminal TM of the cable CB. The connection pattern may be disposed on one side where the signal wiring layer 100 is in contact with the insertion groove 300. For example, a first connection pattern 111 may be disposed on one side of the first signal wiring layer 110 that is in contact with the insertion groove 300. Alternatively or additionally, a second connection pattern 121 may be disposed on one side of the second signal wiring layer 120 that is in contact with the insertion groove 300. In this circumstance, the first connection pattern 111 and/or the second connection pattern 121 may be electrically connected to the terminal TM of the cable CB. That is, the first signal wiring layer 110 and/or the second signal wiring layer 120 may be electrically connected to each other through the terminal TM of the cable CB. Accordingly, the pattern of the first signal wiring layer 110 and the pattern of the second signal wiring layer 120 may be partially or fully electrically connected depending on the design.

Referring to FIG. 1C, the connection pattern 111 of the first signal wiring layer 110 may be disposed on one side in contact with the insertion groove 300, and/or the connection pattern 121 of the second signal wiring layer 120 may be disposed on one side in contact with the insertion groove 300. The connection pattern 111 of the first signal wiring layer 110 may be connected to the first contact CT1 of the terminal TM of the cable CB, and the connection pattern 121 of the second signal wiring layer 120 may be connected to the second contact CT2 of the terminal TM of the cable CB. Accordingly, the first signal wiring layer 110 and the second signal wiring layer 120 may be electrically connected to each other.

The printed circuit board 10 according to exemplary embodiments may include an insulating layer 200. The insulating layer 200 may be disposed between signal wiring layers 100, and may electrically insulate two signal wiring layers 100 disposed on both sides of the insulating layer 200 opposite to each other by spacing them apart. The insulating layer 200 may serve as a substrate on which the signal wiring layer 100 may be placed. For example, the insulating layer 200 may include epoxy resin or Flame Retardant 4 (FR-4) which is a glass fiber containing the same. By forming a cavity in the insulating layer 200, a hole or via that electrically connects the signal wiring layer 100 may be provided in the cavity. The insulating layer 200 may be a core layer or a prepreg layer depending on its arrangement. The prepreg may be harder than the core and may have a different dielectric constant than the core. Referring to FIGS. 1A to 1D, the insulating layer 200 disposed between the first wiring layer 110 and the second wiring layer 120 may be a core layer.

The printed circuit board 10 according to exemplary embodiments may include an insertion groove 300, and the insertion groove 300 may be formed on the first side surface S1 of the insulating layer 200 and may be configured such that the terminal TM of the cable CB may be inserted therein. In one area of the insulating layer 200, the length of the insulating layer 200 along the second direction D2 intersecting or perpendicular to the first direction D1 may be shorter than the length of the first signal wiring layer 110 along the second direction D2 or the length of the second signal wiring layer 120 along the second direction D2. Because the insulating layer 200 is covered by the first signal wiring layer 110 and the second signal wiring layer 120 which are disposed on both sides of the insulating layer 200 located opposite to each other in the first direction D1, the insertion groove 300 may be formed on the first side surface S1 of the insulating layer 200 whose two sides are surrounded by at least a portion of the first signal wiring layer 110 and the second signal wiring layer 120. Both sides of the insulating layer 200 located opposite to each other in the first direction D1 may refer to two sides perpendicular to the first direction D1. The insertion groove 300 may be a cavity into which the terminal TM of the first cable CB may be inserted.

According to some embodiments, a planar shape of an opening of the insertion groove 300 may be rectangular. For example, the planar shape of the opening of the insertion groove 300 may include four sides, and two opposing sides among the four sides may be sides that are in contact with the first signal wiring layer 110 and the second signal wiring layer 120, respectively. The remaining two sides facing each other among the four sides may be sides that are in contact with the insulating layer 200. However, without being limited thereto, the planar shape of the opening of the insertion groove 300 may be selected as one of various shapes in consideration of the terminal shape of the cable CB, or the like.

As described herein, a connection pattern 111 of the first signal wiring layer 110 may be disposed on one side of the first signal wiring layer 110 that is in contact with the insertion groove 300. A portion of the connection pattern 111 of the first signal wiring layer 110 may be exposed inside the insertion groove 300, and thus, when the terminal TM of the cable CB is inserted into the insertion groove 300, the portion of the connection pattern 111 may come into contact with the first contact CT1 of the terminal TM. Similarly, a connection pattern 121 of the second signal wiring layer 120 may be disposed on one side of the second signal wiring layer 120 that meets the insertion groove 300. The connection pattern 121 of the second signal wiring layer 120 may be disposed facing the connection pattern 111 of the first signal wiring layer 110. A portion of the connection pattern 121 of the second signal wiring layer 120 may be exposed inside the insertion groove 300, and thus, when the terminal TM of the cable CB is inserted into the insertion groove 300, the portion of the connection pattern 121 may come into contact with the second contact CT2 of the terminal TM.

The printed circuit board 10 according to exemplary embodiments may include an insertion groove 300 formed on one side surface of the printed circuit board 10, so that the printed circuit board 10 may not include a connector separately mounted on the printed circuit board 10 for connection to an external connection means such as a cable. Accordingly, the cost of manufacturing a printed circuit board 10 may be reduced. In addition, when a connector is mounted on a printed circuit board, a hole for this purpose may be manufactured, and soldering is performed during hole creation, which may affect the solder defect rate. The printed circuit board 10 according to some embodiments does not include a connector, thereby eliminating problems caused by a separate process such as soldering when mounting a connector, and eliminating problems caused by corrosion of a connector exposed to the outside. A typical printed circuit board may have constraints that, when designing holes and/or vias, except for the patterns of the signal wiring layers connected through the holes and/or vias, the patterns of the remaining signal wiring layers need to be spaced apart from the holes and/or vias. According to exemplary embodiments, in a printed circuit board 10, two signal wiring layers 100 that are in contact with a contact CT of a terminal TM of a cable CB may be connected to each other through the terminal TM of the cable CB coupled to an insertion groove 300, so that the number of holes and/or vias for connecting the signal wiring layers 100 to each other may be reduced. Accordingly, the degree of freedom in pattern design may be increased in manufacturing printed circuit boards.

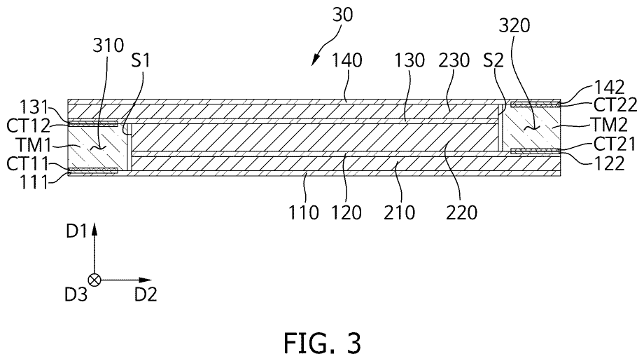

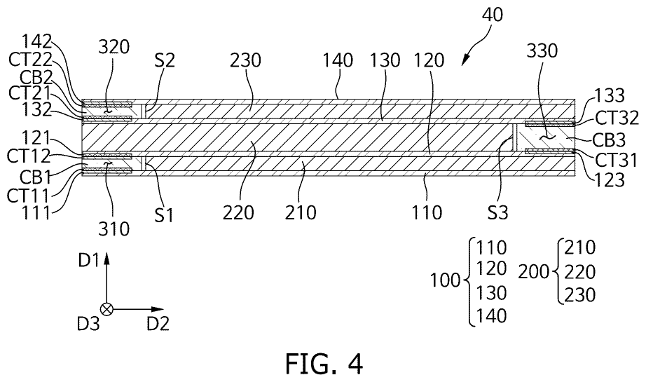

FIG. 2 is a cross-sectional view of the printed circuit board according to exemplary embodiments. FIG. 3 is a cross-sectional view of a printed circuit board according to exemplary embodiments. FIG. 4 is a cross-sectional view of a printed circuit board according to exemplary embodiments.

Referring to FIGS. 2 to 4, each of printed circuit boards 20, 30, and 40 according to the exemplary embodiments may include first to fourth signal wiring layers 110, 120, 130, and 140. The first to fourth signal wiring layers 110, 120, 130, and 140 may be sequentially stacked along the first direction D1. An insulating layer 200 may be disposed between two adjacent signal wiring layers 100. Specifically, a first insulating layer 210 may be placed between the first signal wiring layer 110 and the second signal wiring layer 120. A second insulating layer 220 may be placed between the second signal wiring layer 120 and the third signal wiring layer 130. A third insulating layer 230 may be placed between the third signal wiring layer 130 and the fourth signal wiring layer 140. For example, the first insulating layer 210 and the third insulating layer 230 may be prepreg layers, and the second insulating layer 220 may be a core layer.

A first insertion groove 310 may be formed on a first side surface S1 of at least one of the first to third insulating layers 210, 220, and 230. The first insertion groove 310 may be configured so that the terminal TM1 of the first cable may be inserted therein. Each of the two signal wiring layers in contact with both sides of the first insertion groove 310 located opposite to each other in the first direction D1 may include a connection pattern disposed on one side in contact with the first insertion groove 310. Each connection pattern may be electrically connected to the terminal TM1 of the first cable. That is, the two signal wiring layers that are in contact with both sides of the first insertion groove 310 located opposite to each other in the first direction D1 may be electrically connected to the terminal TM1 of the first cable, respectively. Accordingly, the patterns of the two signal wiring layers may be electrically connected partially or fully, as required.

Depending on the two signal wiring layers that are in contact with both sides of the first insertion groove 310 located opposite to each other in the first direction D1, the length of the first insertion groove 310 in the first direction D1 may be selected.

Alternatively or additionally, a second insertion groove 320 may be formed on the second side surface S2 of at least one of the first to third insulating layers 210, 220, and 230. The terminal TM2 of the second cable may be configured to be inserted into the second insertion groove 320. At least one of the two signal wiring layers that are in contact with both sides of the second insertion groove 320 located opposite to each other in the first direction D1 may include a connection pattern that is disposed on one side thereof in contact with the second insertion groove 320 and is configured to be electrically connectable to a terminal TM2 of the second cable.

The second side surface S2 may be a surface parallel to the first side surface S1. According to some embodiments, the first side surface S1 and the second side surface S2 may be surfaces included in a single plane. In this circumstance, the terminal TM1 of the first cable and the terminal TM2 of the second cable may be inserted in a parallel direction. According to some embodiments, the first side surface S1 and the second side surface S2 may be parallel surfaces included on different planes. In this circumstance, when the printed circuit board 20, 30, and/or 40 is viewed in the third direction, both the first side surface S1 and the second side surface S2 may be exposed.

In this circumstance, the lengths of the first insertion groove 310 and the second insertion groove 320 along the second direction D2 may be different. Alternatively, when the printed circuit board 20, 30, and/or 40 is viewed in the third direction, the first side surface S1 may be exposed, and when viewed in a fourth direction opposite to the third direction, the second side surface S2 may be exposed. In this circumstance, the first insertion groove 310 and the second insertion groove 320 may be disposed on both sides of the printed circuit board 20, 30, and/or 40 opposite to each other in the third direction, respectively. In this circumstance, the terminal TM1 of the first cable and the terminal TM2 of the second cable may be inserted in opposite directions.

Alternatively, a plane including the second side surface S2 and a plane including the first side surface S1 in the printed circuit board 20, 30, and 40 may intersect each other. That is, the plane including the second side surface S2 and the plane including the first side surface S1 may intersect in a straight line. In this circumstance, the terminal TM1 of the first cable and the terminal TM2 of the second cable may be inserted into the printed circuit board 20, 30, and/or 40 in directions intersecting each other.

Similarly, each of the two signal wiring layers in contact with both sides of the second insertion groove 320 located opposite to each other in the first direction D1 may include a connection pattern disposed on one side in contact with the second insertion groove 320. Each connection pattern may be electrically connected to the terminal TM2 of the second cable. That is, the two signal wiring layers that are in contact with both sides of the second insertion groove 320 located opposite to each other in the first direction D1 may be electrically connected to each other through the terminal TM2 of the second cable. Accordingly, the patterns of the two signal wiring layers may be electrically connected partially or fully depending on the design.

At least one of the two signal wiring layers that are in contact with both sides of the second insertion groove 320 located opposite to each other in the first direction D1 may be different from at least one of the two signal wiring layers that are in contact with both sides of the first insertion groove 310 located opposite to each other in the first direction D1. In other words, a signal wiring layer set which is in contact with both sides of the first insertion groove 310 may not overlap with a signal wiring layer set which is in contact with both sides of the second insertion groove 320. For example, the signal wiring layer set which is in contact with both sides of the first insertion groove 310 may include a first signal wiring layer 110 and a second signal wiring layer 120. In this circumstance, the signal wiring layer set which is in contact with both sides of the second insertion groove 320 may include a first signal wiring layer 110 and a third signal wiring layer 130, the first signal wiring layer 110 and a fourth signal wiring layer 140, a second signal wiring layer 120 and the fourth signal wiring layer 140, or the third signal wiring layer 130 and the fourth signal wiring layer 140. However, without being limited thereto, to electrically connect the spaced portions of the first signal wiring layer 110 and the second signal wiring layer 120, the signal wiring layer set that is in contact with both sides of the second insertion groove 320 may include the first signal wiring layer 110 and the second signal wiring layer 120.

Referring to FIG. 2, a printed circuit board 20 according to exemplary embodiments may have a first insertion groove 310 formed on a first side surface S1 of the first to third insulating layers 210, 220, and 230. In this circumstance, a part of the first insertion groove 310 may be formed on the first side surface S1 of the first insulating layer 210, another part of the first insertion groove 310 may be formed on the first side surface S1 of the second insulating layer 220, and another part of the first insertion groove 310 may be formed on the first side surface S1 of the third insulating layer 230. Additionally, the remaining portion of the first insertion groove 310 may be formed on at least one side surface of the signal wiring layer 100. The first signal wiring layer 110 and the fourth signal wiring layer 140, which are in contact with both sides of the first insertion groove 310 located opposite to each other in the first direction D1, may be electrically connected to each other through the terminal TM1 of the first cable that may be inserted into the first insertion groove 310. The contacts CT11 and/or CT12 of the terminal TM1 of the first cable may be electrically connected by coming into contact with the connection pattern 111 of the first signal wiring layer 110 and the connection pattern 141 of the fourth signal wiring layer 140, respectively. According to some embodiments, the printed circuit board 20 may have a second insertion groove 320 formed on a second side surface S2 of the second insulating layer 220. At least one of the second signal wiring layer 120 and the third signal wiring layer 130 that are in contact with both sides of the second insertion groove 320 located opposite to each other in the first direction D1 may be different from at least one of the first signal wiring layer 110 and the fourth signal wiring layer 140 that are in contact with both sides of the first insertion groove 310 located opposite to each other in the first direction D1. The second signal wiring layer 120 and the third signal wiring layer 130 may be electrically connected to each other through a terminal TM2 of a second cable that may be inserted into the second insertion groove 320. The contacts CT21 and/or CT22 of the terminal TM2 of the second cable may be electrically connected by coming into contact with the connection pattern 122 of the second signal wiring layer 120 and the connection pattern 132 of the third signal wiring layer 130, respectively.

According to some embodiments, the length of the second signal wiring layer 120 along the second direction D2 of the printed circuit board 20 according to exemplary embodiments may be shorter than the shorter length out of the length of the first signal wiring layer 110 along the second direction D2 or the length of the fourth signal wiring layer 140 along the second direction D2. The length of the third signal wiring layer 130 along the second direction D2 may be shorter than the shorter length out of the length of the first signal wiring layer 110 along the second direction D2 or the length of the fourth signal wiring layer 140 along the second direction D2. For example, the length of the second signal wiring layer 120 along the second direction D2 and the length of the third signal wiring layer 130 along the second direction D2 may be substantially the same. However, without being limited thereto, the length of the second signal wiring layer 120 along the second direction D2 and the length of the third signal wiring layer 130 along the second direction D2 may be different from each other depending on the presence or absence of the insertion groove 300, the size of the insertion groove 300, and/or the positional relationship between the insertion grooves 300.

Referring to FIG. 3, in a printed circuit board 30 according to exemplary embodiments, a first insertion groove 310 may be formed on a first side surface S1 of the first and second insulating layers 210 and 220. In this circumstance, a part of the first insertion groove 310 may be formed on the first side surface S1 of the first insulating layer 210, and another part of the first insertion groove 310 may be formed on the first side surface S1 of the second insulating layer 220. Additionally, the remaining portion of the first insertion groove 310 may be formed on at least one side surface of the signal wiring layer 100. The first signal wiring layer 110 and the third signal wiring layer 130, which are disposed on both sides of the first insertion groove 310 located opposite to each other in the first direction D1, may be electrically connected to each other through the terminal TM1 of the first cable that may be inserted into the first insertion groove 310. The contacts CT11 and/or CT12 of the terminal TM1 of the first cable may be electrically connected by coming into contact with the connection pattern 111 of the first signal wiring layer 110 and the connection pattern 131 of the third signal wiring layer 130, respectively.

According to some embodiments, in a printed circuit board 30, a second insertion groove 320 may be formed on a second side surface S2 of the second and third insulating layers 220, 230. At least one of the second signal wiring layer 120 and the fourth signal wiring layer 140 that are in contact with both sides of the second insertion groove 320 located opposite to each other in the first direction D1 may be different from at least one of the first signal wiring layer 110 and the third signal wiring layer 130 that are in contact with both sides of the first insertion groove 310 located opposite to each other in the first direction D1. The second signal wiring layer 120 and the fourth signal wiring layer 140 may be electrically connected to each other through a terminal TM2 of a second cable that may be inserted into the second insertion groove 320. The contacts CT21 and/or CT22 of the terminal TM2 of the second cable may be electrically connected by coming into contact with the connection pattern 122 of the second signal wiring layer 120 and the connection pattern 142 of the fourth signal wiring layer 140, respectively.

According to some embodiments, the length of the second signal wiring layer 120 along the second direction D2 of the printed circuit board 30 may be shorter than the shorter length out of the length of the first signal wiring layer 110 along the second direction D2 or the length of the fourth signal wiring layer 140 along the second direction D2. The length of the third signal wiring layer 130 along the second direction D2 may be shorter than the shorter length out of the length of the first signal wiring layer 110 along the second direction D2 or the length of the fourth signal wiring layer 140 along the second direction D2. For example, the length of the second signal wiring layer 120 along the second direction D2 and the length of the third signal wiring layer 130 along the second direction D2 may be substantially the same.

Referring to FIG. 4, in a printed circuit board 40 according to exemplary embodiments, a first insertion groove 310 may be formed on a first side surface S1 of a first insulating layer 210. The first signal wiring layer 110 and the second signal wiring layer 120 disposed on both bottom surfaces of the first insertion groove 310 in the first direction D1 may be electrically connected to each other through the terminal TM1 of the first cable that may be inserted into the first insertion groove 310. The contacts CT11 and/or CT12 of the terminal TM1 of the first cable CB1 may be electrically connected by coming into contact with the connection pattern 111 of the first signal wiring layer 110 and the connection pattern 121 of the second signal wiring layer 120, respectively.

According to some embodiments, a printed circuit board 40 may have a second insertion groove 320 formed on a second side surface S2 of a third insulating layer 230. The first side surface S1 and the second side surface S2 may be parallel to each other. According to some embodiments, the first side surface S1 and the second side surface S2 may be surfaces included in a single plane. At least one of the third signal wiring layer 130 and the fourth signal wiring layer 140 that are disposed in both sides of the second insertion groove 320 located opposite to each other in the first direction D1 may be different from at least one of the first signal wiring layer 110 and the second signal wiring layer 120 that are disposed in both sides of the first insertion groove 310 located opposite to each other in the first direction D1. The third signal wiring layer 130 and the fourth signal wiring layer 140 may be electrically connected to each other through a terminal TM2 of a second cable CB2 that may be inserted into the second insertion groove 320. The contacts CT21 and/or CT22 of the terminal TM2 of the second cable may be electrically connected by coming into contact with the connection pattern 132 of the third signal wiring layer 130 and the connection pattern 142 of the fourth signal wiring layer 140, respectively.

According to some embodiments, in the printed circuit board 40, a third insertion groove 330 may be formed on a third side surface S3 of the second insulating layer 220. The first side surface S1 and the third side surface S3 may be parallel to each other. The first side surface S1 and the third side surface S3 may be parallel planes facing the outside in opposite directions based on the printed circuit board 40. At least one of the second signal wiring layer 120 and the third signal wiring layer 130 that are disposed in both sides of the third insertion groove 330 located opposite to each other in the first direction D1 may be different from at least one of the first signal wiring layer 110 and the second signal wiring layer 120 that are disposed in both sides of the first insertion groove 310 located opposite to each other in the first direction D1. In addition, at least one of the second signal wiring layer 120 and the third signal wiring layer 130 that are disposed in both sides of the third insertion groove 330 located opposite to each other in the first direction D1 may be different from at least one of the third signal wiring layer 130 and the fourth signal wiring layer 140 that are disposed in both sides of the second insertion groove 320 located opposite to each other in the first direction D1. The second signal wiring layer 120 and the third signal wiring layer 130 may be electrically connected to each other through a terminal of a third cable CB3 that may be inserted into the third insertion groove 330. The contacts CT31 and/or CT32 of the terminal TM3 of the third cable CB3 may be electrically connected by coming into contact with the connection pattern 123 of the second signal wiring layer 120 and the connection pattern 133 of the third signal wiring layer 130, respectively.

According to some embodiments, the length of the second signal wiring layer 120 along the second direction D2 of the printed circuit board 40 may be substantially the same as the length of the first signal wiring layer 110 along the second direction D2 or the length of the fourth signal wiring layer 140 along the second direction D2. The length of the third signal wiring layer 130 along the second direction D2 may be substantially the same as the length of the first signal wiring layer 110 along the second direction D2 or the length of the fourth signal wiring layer 140 along the second direction D2.

The printed circuit boards 20, 30, and 40 according to exemplary embodiments may include a plurality of signal wiring layers 100 and may include an insertion groove 300 electrically connecting two of the plurality of signal wiring layers 100 to each other. Two signal wiring layers contacting opposite sides along the first direction D1 of the insertion groove 300 may be selected as needed, and thus, printed circuit boards of various configurations may be provided. Exemplary embodiments for the printed circuit boards 20, 30, and 40 including first to fourth signal wiring layers have been described with reference to FIGS. 2 to 4, and without being limited thereto, the present disclosure may also be applied to a printed circuit board including a different number of signal wiring layers.

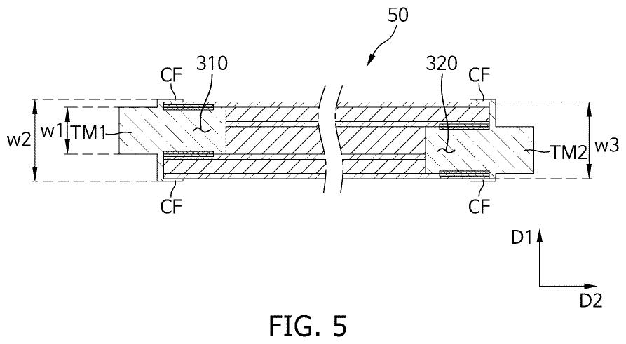

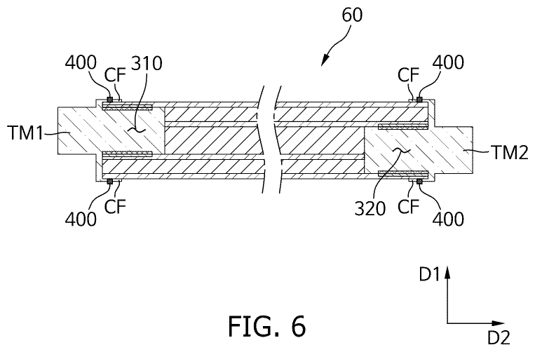

FIG. 5 is a cross-sectional view of a printed circuit board according to exemplary embodiments. FIG. 6 is a cross-sectional view of a printed circuit board according to exemplary embodiments.

Referring to FIG. 5, the thickness w1 of the first insertion groove 310 of the printed circuit board 50 according to exemplary embodiments along the first direction D1 may be smaller than the thickness w2 of the terminal TM1 of the first cable along the first direction D1. In some embodiments, the thickness w3 of the printed circuit board 50 according to exemplary embodiments may be smaller than the thickness w2 of the terminal TM1 of the first cable along the first direction. In this circumstance, the thickness w2 of the terminal TM1 of the first cable along the first direction D1 may correspond to the length of the major axis among the thicknesses along the first direction D1 on the cross-section of the terminal TM1 of the first cable. A portion of the terminal TM1 of the first cable may have a thickness along the first direction that is smaller than or substantially equal to the thickness w1 along the first direction D1 of the first insertion groove 310, and thus the portion of the terminal TM1 may be inserted into the first insertion groove 310. Another part of the terminal TM1 of the first cable may have a thickness along the first direction D1 that is greater than the thickness w1 along the first direction D1 of the first insertion groove 310, and thus the other part of the terminal TM1 may be positioned outside the first insertion groove 310 without being inserted into the first insertion groove 310.

The terminal TM1 of the first cable may include a fixing portion CF, and the fixing portion CF may be disposed on both side surfaces of the terminal TM1 of the first cable along the first direction D1. When the terminal TM1 of the first cable is inserted into the first insertion groove 310, the fixing portion CF may be disposed on both outer surfaces of the printed circuit board 50 located opposite to each other in the first direction D1. Through the fixing portion CF, the terminal TM1 of the first cable and the printed circuit board 50 may be more firmly fixed. Accordingly, poor contact between the printed circuit board 50 and the terminal TM1 of the cable may be reduced.

The description of the first insertion groove 310 and the terminal TM1 of the first cable may be equally applied to the description of the second insertion groove 320 and the second terminal TM2.

Referring to FIG. 6, the printed circuit board 60 according to exemplary embodiments may further include a cable holder 400. For example, the cable holder 400 may be disposed on at least one of two signal wiring layers respectively located on both outer surfaces of the printed circuit board 60 located opposite to each other in the first direction D1. The cable holder 400 may be configured to engage with the fixing portion CF of the terminal TM1 of the first cable. For example, the fixing portion CF may be inserted into an opening formed by the cable holder 400. The cable holder may be disposed on at least one of the first or second signal wiring layers, as described herein.

Through the cable holder 400 and the fixing portion CF inserted into the opening formed by the cable holder 400, the terminal TM1 of the first cable and the printed circuit board 60 may be more firmly fixed. Accordingly, poor contact between the printed circuit board 60 and the terminal TM1 of the cable may be reduced.

The description of the first insertion groove 310 and the terminal TM1 of the first cable may be equally applied to the description of the second insertion groove 320 and the second terminal TM 2.

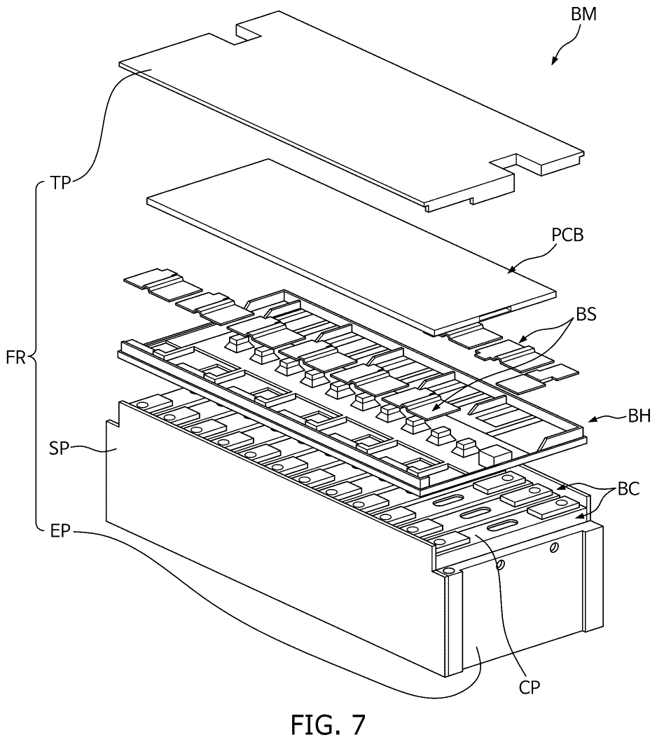

FIG. 7 is a perspective view of a battery module according to exemplary embodiments.

Referring to FIG. 7, a battery module BM according to exemplary embodiments may include a plurality of battery cells BC, a printed circuit board PCB, and a bus bar BS electrically connecting the plurality of battery cells BC and the printed circuit board PCB. Here, the printed circuit board PCB may include a first insulating layer, and a first signal wiring layer and a second signal wiring layer spaced apart from each other in one direction with the first insulating layer interposed therebetween. The printed circuit board PCB may include a first insertion groove which is formed on a first side surface of the first insulating layer and into which a terminal of a first cable may be inserted. Additionally, at least one of the first signal wiring layer or the second signal wiring layer may include a connection pattern disposed on one side in contact with the first insertion groove and configured to be electrically connectable with the terminal of the first cable.

The battery cells BC, the busbar BS, and the printed circuit board PCB may be sequentially stacked and accommodated in a frame FR. The frame FR may include a top plate TP covering the upper portion of the battery module BM, a side plate SP covering the side surface of the battery module BM, and an end plate EP.

The battery module BM according to exemplary embodiments may include a plurality of battery cells BC. For example, in the battery module BM, a plurality of battery cells BC may be disposed in one direction so that their wide surfaces face each other.

According to some embodiments, each battery cell BC may include a case, an electrode assembly accommodated together with an electrolyte inside the case, and a cap plate CP for sealing the case. The electrode assembly may be formed by sequentially winding or stacking a negative electrode plate, a separator, and a positive electrode plate. The negative electrode plate may be formed of a metal foil such as copper, copper alloy, nickel or nickel alloy and may be applied or coated with a negative electrode active material such as graphite or carbon. The positive electrode plate may be formed of a metal foil such as aluminum or an aluminum alloy and may be applied or coated with an active material such as a transition metal oxide. A non-coated portion, in which no active material is applied, may be formed on each of the negative electrode plate and the positive electrode plate. A negative tab may be connected to the negative non-coated portion, and a positive tab may be connected to the positive non-coated portion. The negative tab and positive tab connected in this way may be electrically connected to the negative terminal and positive terminal formed on the cap plate CP, respectively. The negative terminal and positive terminal formed on the cap plate CP may be electrically connected to the bus bar BS. However, the structure of the battery cell BC is not limited to this and may be appropriately changed as needed. In addition, the number and arrangement of battery cells BC are not limited to the structure shown in FIG. 7 and may be appropriately changed as needed.

A plurality of battery cells BC may be accommodated in a frame FR. According to some embodiments, the frame FR may include a pair of end plates EP that contact the outermost battery cells BC in the arrangement direction of the battery cells BC, a pair of side plates SP that are joined perpendicularly to the end plates EP, and a top plate TP that is disposed on top of a printed circuit board PCB. Although not shown, a bottom plate is provided at the bottom of the battery cells BC to support the battery cells BC from below. The battery cells BC, the busbar holder BH, the busbar BS, and the printed circuit board PCB may be accommodated inside the frame FR.

The busbar holder BH may be placed above the cap plate CP as shown in FIG. 7 and may support the busbar BS. The busbar holder BH may be, for example, a rectangular plate and may be manufactured from an insulating material.

A plurality of through holes may be formed in the busbar holder BH to expose the positive and negative terminals of the cap plate CP. The positive and negative terminals may be exposed through through holes formed in the busbar holder BH, and the busbar BS may be electrically connected to the exposed positive and negative terminals.

The bus bar BS may electrically connect the positive terminal and the negative terminal. The busbar BS may connect a plurality of battery cells BC in series and/or parallel. For this purpose, a plurality of bus bars BS may be provided. According to some embodiments, the bus bar BS may electrically connect the positive terminal of a battery cell BC to the positive terminal or negative terminal of another battery cell BC. Alternatively, the busbar BS may electrically connect the negative terminal of a battery cell BC to the positive terminal or negative terminal of another battery cell BC. The bus bar BS may be connected to the positive terminal and/or negative terminal by welding or other methods. The area of the battery cell BC other than the positive terminal and negative terminal may be insulated from the busbar BS by the busbar holder BH. A printed circuit board PCB may be interposed between the bus bar BS and the top plate TP, and the bus bar BS may be electrically connected to the printed circuit board PCB.

Various components for measuring status information on the battery cell BC, such as voltage and/or temperature of the battery cell BC, and various elements or circuits for controlling and/or managing the battery cell BC may be mounted on the printed circuit board PCB. In some embodiments, the printed circuit board PCB may include a battery management system (BMS). In some embodiments, the printed circuit board PCB may be electrically connected to the exterior of the battery module BM via a separate cable. In this circumstance, the printed circuit board PCB may be a printed circuit board 10, 20, 30, 40, 50, or 60 described in relation to FIGS. 1A to 6.

Referring to FIGS. 1A to 6, a description of the printed circuit board PCB included in the battery module BM of FIG. 7 has been described elsewhere herein, and thus a detailed description thereof will be omitted.

Although the present disclosure has been described with reference to embodiments and drawings illustrating aspects thereof, the present disclosure is not limited thereto. Various modifications and variations can be made by a person skilled in the art to which the present disclosure belongs within the scope of the technical spirit of the present disclosure and the claims and their equivalents, below.

What is claimed is:

1. A printed circuit board comprising:
a first signal wiring layer;
a second signal wiring layer disposed spaced apart from the first signal wiring layer along a first direction;
a first insulating layer disposed between the first signal wiring layer and the second signal wiring layer; and
a first insertion groove formed on a first side surface of the first insulating layer and configured such that a terminal of a first cable can be inserted therein,
wherein at least one of the first signal wiring layer or the second signal wiring layer includes a connection pattern which is disposed on one side thereof in contact with the first insertion groove and configured to be electrically connected to the terminal of the first cable.

2. The printed circuit board according to claim 1, wherein:
the first signal wiring layer includes a first connection pattern disposed on the one side thereof in contact with the first insertion groove,
the second signal wiring layer includes a second connection pattern disposed on the one side thereof in contact with the first insertion groove, and
the first connection pattern and the second connection pattern are configured to be electrically connected to the terminal of the first cable, respectively.

3. The printed circuit board according to claim 1, wherein the first insulating layer includes a core layer or a prepreg layer.

4. The printed circuit board according to claim 1, further comprising:
a third signal wiring layer disposed on the second signal wiring layer; and
a second insulating layer disposed between the second signal wiring layer and the third signal wiring layer,
wherein at least a portion of the first insertion groove is formed on one side surface of the second insulating layer.

5. The printed circuit board according to claim 4, wherein a length of the second signal wiring layer in a second direction intersecting the first direction is shorter than a length of the first signal wiring layer or the third signal wiring layer in the second direction.

6. The printed circuit board according to claim 4, wherein:
the first insulating layer includes one of a core layer and a prepreg layer, and
the second insulating layer includes the other of the core layer or the prepreg layer.

7. The printed circuit board according to claim 4, further comprising:
a fourth signal wiring layer disposed on the third signal wiring layer; and
a third insulating layer disposed between the third signal wiring layer and the fourth signal wiring layer,
wherein at least a portion of the first insertion groove is formed on one side surface of the third insulating layer.

8. The printed circuit board according to claim 1, further comprising:
a third signal wiring layer disposed on the second signal wiring layer;
a second insulating layer disposed between the second signal wiring layer and the third signal wiring layer;
a fourth signal wiring layer disposed on the third signal wiring layer;
a third insulating layer disposed between the third signal wiring layer and the fourth signal wiring layer; and
a second insertion groove which is formed on a second side surface of at least one of the first to third insulating layers and configured such that a terminal of a second cable can be inserted therein,
wherein at least one of two signal wiring layers respectively contacting both sides of the second insertion groove located opposite to one another in the first direction includes a connection pattern that is disposed on one side thereof in contact with the second insertion groove and configured to be electrically connected to a terminal of the second cable.

9. The printed circuit board according to claim 8, wherein:
one of the two signal wiring layers includes a third connection pattern disposed on one side thereof in contact with the second insertion groove,
the other of the two signal wiring layers includes a fourth connection pattern disposed on one side thereof in contact with the second insertion groove, and
the third connection pattern and the fourth connection pattern are configured to be electrically connected to the terminal of the second cable, respectively.

10. The printed circuit board according to claim 8, wherein at least one of the two signal wiring layers is different from at least one of the two signal wiring layers that are in contact with opposite sides along the first direction of the first insertion groove.

11. The printed circuit board according to claim 8, wherein the second side surface is a surface parallel to the first side surface.

12. The printed circuit board according to claim 8, wherein a plane including the second side surface intersects a plane including the first side surface.

13. The printed circuit board according to claim 1, wherein a thickness of the first insertion groove in the first direction is smaller than a thickness of the terminal of the first cable in the first direction.

14. The printed circuit board according to claim 13, further comprising:
a cable holder that is disposed on at least one of the first signal wiring layer or the second signal wiring layer and configured to engage with the terminal of the first cable.

15. The printed circuit board according to claim 1, wherein a planar shape of an opening of the first insertion groove is rectangular.

16. A battery module comprising:
a plurality of battery cells;
a printed circuit board including a first insulating layer, and a first signal wiring layer and a second signal wiring layer spaced apart from one another in a first direction with the first insulating layer interposed therebetween; and
a bus bar that electrically connects the plurality of battery cells and the printed circuit board,
wherein the printed circuit board further includes a first insertion groove which is formed on a first side surface of the first insulating layer and into which a terminal of a first cable can be inserted, and
wherein at least one of the first signal wiring layer or the second signal wiring layer includes a connection pattern which is disposed on one side thereof in contact with the first insertion groove and configured to be electrically connected to the terminal of the first cable.

17. The battery module according to claim 16, wherein:
the first signal wiring layer includes a first connection pattern on the one side in contact with the first insertion groove,
the second signal wiring layer includes a second connection pattern on the one side in contact with the first insertion groove, and
the first connection pattern and the second connection pattern are configured to be electrically connected to the terminal of the first cable, respectively.

18. The battery module according to claim 16, further comprising:
a third signal wiring layer disposed on the second signal wiring layer;
a second insulating layer disposed between the second signal wiring layer and the third signal wiring layer;
a fourth signal wiring layer disposed on the third signal wiring layer; and
a third insulating layer disposed between the third signal wiring layer and the fourth signal wiring layer,
wherein at least a portion of the first insertion groove is formed on one side of at least one of the second insulating layer or the third insulating layer.

19. The battery module according to claim 16, further comprising:
a third signal wiring layer disposed on the second signal wiring layer;
a second insulating layer disposed between the second signal wiring layer and the third signal wiring layer;
a fourth signal wiring layer disposed on the third signal wiring layer;
a third insulating layer disposed between the third signal wiring layer and the fourth signal wiring layer; and
a second insertion groove which is formed on a second side surface of at least one of the first to third insulating layers and into which a terminal of a second cable can be inserted,
wherein at least one of two signal wiring layers respectively contacting both sides of the second insertion groove located opposite to one another in the first direction includes a connection pattern disposed on one side thereof in contact with the second insertion groove and configured to be electrically connected to a terminal of the second cable.

20. The battery module according to claim 19, wherein:
one of the two signal wiring layers includes a third connection pattern on one side thereof in contact with the second insertion groove,
the other of the two signal wiring layers includes a fourth connection pattern on one side thereof in contact with the second insertion groove,
the third connection pattern and the fourth connection pattern are configured to be electrically connected to the terminal of the second cable, respectively, and
at least one of the two signal wiring layers is different from at least one of the two signal wiring layers that are in contact with opposite sides along the first direction of the first insertion groove.
